(19) United States
(12) Patent Application Publication
(10) Pub. No.: US 2006/0275934 A1
(43) Pub. Date: Dec. 7, 2006

(54) Management of computer processes

(76) Inventors: William Pohl, Morgan Hill, CA (US); Walter J. Searle, Gilroy, CA (US); Chukwuma Valentine Akpuokwe, Sunnyvale, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/144,166

(22) Filed: Jun. 3, 2005

(51) Int. Cl. H01L 21/66; H01L 23/58; H01L 21/336

(52) U.S. Cl. 438/14; 438/257; 257/48

(57) ABSTRACT

It is determined that an amount of total memory utilized by active processes exceeds a memory pressure threshold. There is deactivated at least one active process occupying space in the total memory during a first system cycle based on said determination. There is deactivated a number N of active processes during succeeding system cycles while the memory pressure threshold is exceeded, where N increases at a non-linear rate during each system cycle until the total memory utilized by active processes does not exceed the memory pressure threshold.

### CROSS-REFERENCE TO RELATED APPLICATION

This application contains subject matter that is related to the subject matter of the following application, which is assigned to the same assignee as this application. The below-listed application is hereby incorporated herein by reference in its entirety:

“Prioritization of Computer Processes,” by W. Pohl, W. Searle, C. Akpuokwe and B. Szonye, application Ser. No. ______, co-filed herewith.

### BACKGROUND

Computer operating systems and/or computer language/applications often need to deal with memory allocation. Some memory management techniques address how to allocate available memory in order to make the most efficient use of the available memory without incurring substantial overhead processing which can lead to time delays in processing capability. These techniques address how available blocks of memory are to be assigned and how garbage collection, the harvesting of memory space previously occupied by a process that has been terminated or released, will be accomplished.

A different type of memory management in one example is required when the total amount of available free memory is being approached due to increasing memory requirements. This is typically due to the spawning of more processes that in one example are serviced by the computing environment or an increase in memory requirements by running processes. A known approach for preventing memory overrun utilizes a threshold representing a predetermined amount of free memory remaining. When this threshold is reached, active processes (processes that do not have to be relocated from another storage location to utilize computational resources) are deactivated, i.e., moved from active memory to virtual memory, i.e., virtual memory is another storage location from which processes have to be move in order to utilize computational resources, one by one over successive time intervals until the memory pressure is relieved, i.e., the amount of free memory is greater than the threshold level.

### SUMMARY

The invention in one implementation encompasses a method for managing processes in a computing system. The method comprises the steps of determining that an amount of total memory utilized by active processes exceeds a memory pressure threshold; deactivating at least one active process occupying space in the total memory during a first system cycle based on said determination; and deactivating a number N of active processes during succeeding system cycles while the memory pressure threshold is exceeded, where N increases at a non-linear rate during each system cycle until the total memory utilized by active processes does not exceed the memory pressure threshold.

### DESCRIPTION OF THE DRAWINGS

Features of exemplary implementations of the invention will become apparent from the description, the claims, and the accompanying drawings in which:

FIG. 1 is a block diagram on an exemplary apparatus.

FIG. 2 is a state diagram of exemplary logic that can be implemented using the apparatus of FIG. 1 for deactivating processes in view of memory pressure.

FIG. 3 is a state diagram of exemplary logic that can be implemented using the apparatus of FIG. 1 for reactivating processes.

FIG. 4 represents a table of exemplary parameters and corresponding values that in one example are associated with each process in a computing environment of the apparatus of FIG. 1.

FIG. 5 is a state diagram of exemplary logic that can be implemented using the apparatus of FIG. 1 for determining which specific processes are to be deactivated and reactivated.

### DETAILED DESCRIPTION

Referring to the Background section above, difficulties are encountered in the deactivation and reactivation of processes in view of memory pressure as implemented by current techniques. Deactivating of processes at a linear rate to reduce memory pressure can result in prolonging an unstable or potentially unstable state of the kernel, i.e., a low level portion of the computing environment responsible for execution management. Reactivating of processes at a linear rate when free memory substantially exceeds the memory pressure level in one example could prolong the time required to bring deactivated processes back into an active state to share in computational resources.

Upon reaching a memory pressure threshold, a number of known techniques would typically start deactivating running processes. Running processes that have been identified as being critical would be exempted from potential deactivation. Other running processes in one example will be selected for deactivation. Once a process is deactivated, it would not be considered for reactivation until the memory pressure was alleviated. During the period of memory pressure, processes that were deactivated prior to the beginning of the memory pressure and processes that are deactivated after the initiation of the memory pressure are held in abeyance pending the cessation of the memory pressure. This results in an inequitable sharing of computing resources since one or more deactivated processes may become more deserving of computation resources than some processes that are maintained active during the period of memory pressure. This inequality become especially critical when the period of memory pressure lasts for a substantial time relative to the processing requirements. In addition, the particular processes selected to be deactivated by a number of known techniques result in an inequitable sharing of computational resources during periods of memory pressure.

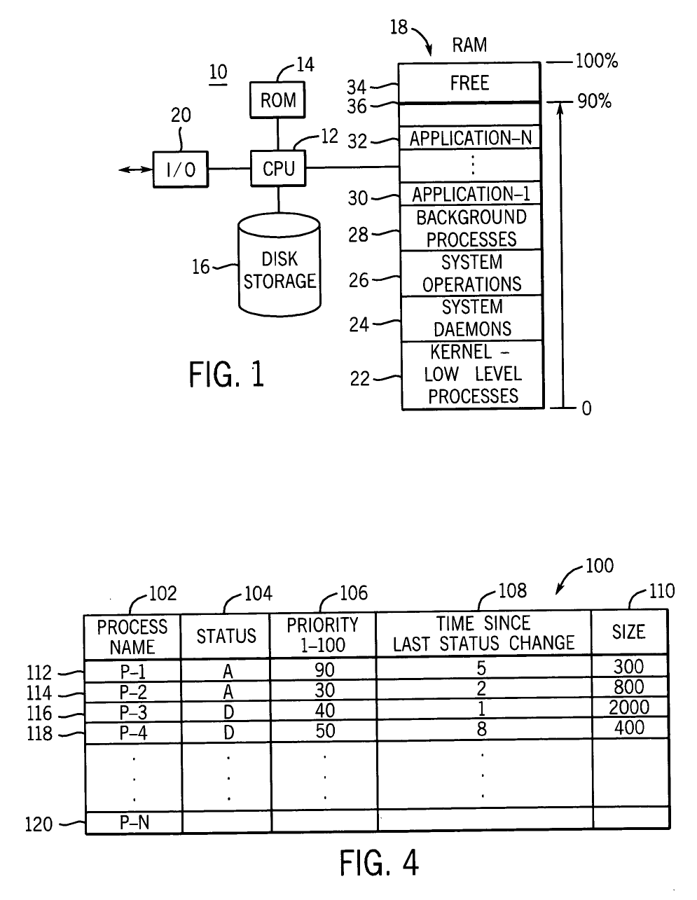

FIG. 1 is a block diagram on an exemplary apparatus or computing system 10 suited for incorporating and executing the illustrative approaches herein. One exemplary implementation is generally directed to the management of processes running in a computing environment when free memory becomes limited. A further exemplary implementation addresses how to select processes to remain active, be deactivated and/or be reactivated during times of memory pressure.

A non-linear arithmetic rate of deactivating and reactivating processes in one example is utilized in order to minimize the time required to reach a stable state of operation due to memory pressure and to minimize the time required to bring deactivated processes back into an active state to maximize the use of computational resources when memory pressure has ceased.

Swapping of a deactivated processes with one or more currently active processes in one example occurs during times of memory pressure based on a fairness algorithm. This makes it possible for a deactivated process to share in the computational resources even during a period of memory pressure. In one example, active and deactivated processes can be swapped in one time interval of the continuum of time intervals during which memory pressure is evaluated, referred to herein as a system cycle. This furthers the capability to provide a more equitable sharing of resources.

A central processing unit (CPU) 12 is supported by read-only memory (ROM) 14, nonvolatile storage media 16 such as a disk drive, random access memory (RAM) 18 and an input/output (I/O) interface module 20. The ROM 14 and storage 16 contain stored program control instructions including the operating system environment for the CPU 12. Upon initialization (start-up) of the computing system, various portions of the operating system environment, i.e., the operating system kernel 22 of low-level processes, will be loaded into RAM 18 for access and use in the control of the CPU 12, other elements of the operating system and the management of other higher level processes. The illustrative approaches herein in one example are suited for utilization in various operating system environments; for explanatory purposes, a UNIX operating environment such as is available from Hewlett-Packard Company (3000 Hanover Street, Palo Alto, Calif. 94304-1185 USA, www.hp.com) is assumed.

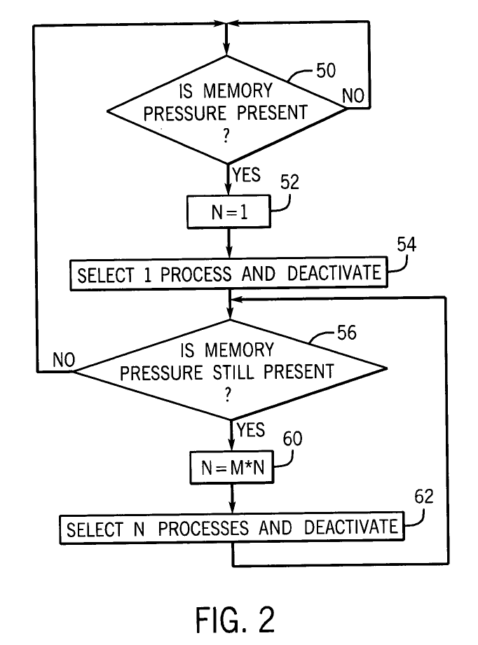

The RAM 18 is depicted as an operational representation containing a plurality of processes and data. One or more active processes and/or data as will be described reside in each of the sections of RAM 18. The operating system kernel 22 consists of a plurality of low-level processes that are created during system start up (init). A plurality of system daemons 24 consists of disk and execution monitors that operate in conjunction with the kernel 22 to provide operational control for the computing system. A system operation section 26 contains processes and data of a higher level that are concerned with the overall operation of each of the components of the computing system. Background processes 28 represent a plurality of processes and services that run in the background from the user's perspective and typically operate to provide higher-level functionality, some of which maybe accessed by the user and/or higher-level programs. A first application program 30 may represent one of a plurality of programs concurrently running and typically under the operational control of the user. The last of such applications is represented as application-N 32. Above application 32 is the amount of free or unused memory 34 available within RAM 18. An exemplary memory pressure threshold level 36 is utilized to determine when memory pressure is being exerted, i.e., when a predetermined minimum amount of free memory exists in order to maintain a stable operating memory environment. In this example, the threshold level has been set to 90% of capacity, i.e., 10% of memory remains free for use. As illustrated in FIG. 1, the amount of free memory 34 is more than 10% and a memory pressure condition does not exist. When the cumulative amount of memory in use reaches or exceeds 90%, in one example a memory pressure condition will be determined to exist. This corresponding implementation will be described below in connection with FIG. 2.

Those skilled in the art will appreciate that the depiction of RAM 18 is intended to provide a functional perspective. Actual memory usage represented by the illustrative sections in FIG. 1 can vary depending upon the operating system and computing environment. For purposes of determining the amount of free memory relative to the memory pressure threshold level 36, some portions of memory that are not being currently utilized may not be determined to be “free” for various reasons. For example, small amounts of discontinuous memory may not be sufficiently useful depending upon the operating environment and may not be considered free for purposes of computing the amount of free memory when determining the memory pressure threshold. It will also be understood that unused memory determined to be free memory in one example may not necessarily be contiguous. In a further example, the specific memory pressure threshold level is a function of the computational system design that may include the nature of the programs normally run on the system as well as any known or projected load volatility.

FIG. 2 is a state diagram illustrating an exemplary logic for deactivating processes due to memory pressure. The actions taken in the elements of FIGS. 2, 3 and 5 can be thought of as being “states” in a state diagram or corresponding “steps” in a closed loop flow diagram. States and steps in one example are interchangeable. A determination is made in step 50 if memory pressure is present. A NO determination by step 50 creates a feedback loop indicating that memory pressure is continually monitored on at least a periodic basis. A YES determination by step 50 results in parameter N being set equal to 1. In step 54 one active process is selected and deactivated. In step 56 a determination is made of whether memory pressure is still present. A NO determination causes a return to determination step 50 to monitor for memory pressure, i.e., the memory pressure has been relieved. A YES determination by step 56 results in parameter N being changed as a non-linear increment, e.g., M*N, where M>1 in step 60. In step 62 a number of processes equal to N are selected and deactivated. Following step 62, control returns to the input of step 56 in which a determination is again made of whether memory pressure is still present.

Referring to FIG. 2, steps 56, 60 and 62 in one example form a loop in which a non-linear increasing number of processes are selected and deactivated until memory pressure ceases. For example, when M=2, the number of processes to be selected and deactivated during each iteration through this loop will double. This loop in one example is traversed once during each system cycle. Such a non-linear increasing, geometric, rate will result in the cessation of the memory pressure in a shorter time interval as compared with a linear rate or fixed predetermined number of processes to be deactivated during each system monitoring cycle. The factor M need not necessarily be an integer, e.g., M=1.5. Although such a non-integer M could lead to a newly calculated N that is also a non-integer, the newly calculated N could be rounded up or down prior to implementing step 62. Various numerical calculations could be used to generate a non-linear increment.

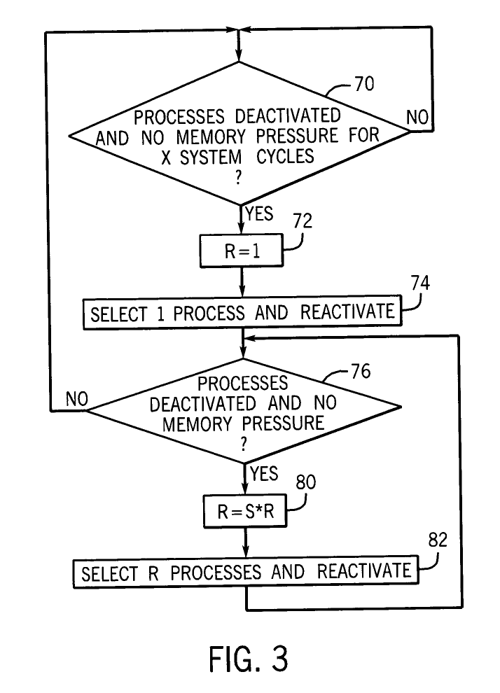

FIG. 3 is a state diagram illustrating exemplary logic for reactivating processes that have been previously deactivated. Such a condition may for example occur due to an overshoot in deactivating processes to eliminate a memory pressure condition. In step 70 a determination is made of whether processes have been deactivated and whether there has been no memory pressure for X system cycles. A NO determination by step 70 creates a feedback loop indicating that these conditions are being continually monitored to determine when the conditions will be satisfied. YES determination by step 70 results in parameter R being set equal to 1. In step 74 one deactivated process is selected and reactivated. In step 76 a determination is made of whether processes remain deactivated and if there is no memory pressure. A NO determination causes a return to determination step 79 since at least one condition of step 76 is not met. A YES determination by step 76 results in parameter R being set equal to S*R, where S>1 in step 80. In step 82 a number of processes equal to R are selected and reactivated. Following step 82, control returns to the input of step 76 in which a determination is again made of whether the specified conditions are satisfied.

Referring to FIG. 3, steps 76, 80 and 82 in one example form a loop in which a non-linear increasing number of processes are selected and reactivated in the absence of memory pressure during each system cycle. For example, when R=2, the number of processes to be selected and reactivated during each iteration through this loop will double. Such a non-linear increasing, geometric, rate will result in the restoration of a greater number of deactivated processes in a shorter time interval as compared with a linear rate or a fixed predetermined number of processes to be reactivated during each system monitoring cycle. The factor S need not necessarily be an integer, e.g., S=1.5. Although such a non-integer S could lead to a newly calculated R that is also a non-integer, the newly calculated R could be rounded up or down prior to implementing step 82.

The approaches described in connection with FIGS. 2 and 3 in one example address the deactivation and reactivation of processes based on a number of processes that can be changed at a geometric rate. Such approaches in one example can also be implemented by considering the amount of memory, i.e., size associated with the corresponding processes, as opposed to the number of different processes. For example, a predetermined amount of memory could be targeted for deactivation or reactivation followed by a non-linear increase in such memory during each iteration. Since processes in one example generally are handled as a whole unit, the memory allocation for deactivation or reactivation could be translated into a corresponding number of processes based on the size of the processes as compared with the targeted memory. For example, to satisfy a given target amount of memory, one relatively large process or three smaller processes of a total size of the large process could be identified to satisfy the targeted memory for deactivation or reactivation during an iteration. Also, once the memory pressure has been alleviated by deactivations or reached during reactivations, the rate of deactivation/reactivation is reset and starts a new deactivation/reactivation cycle with the “normal” rate, e.g., a linear rate, which is maintained unless escalation to the non-linear rate is warranted by a failure to achieve stability at the memory pressure threshold.

FIG. 4 is a representative table 100 illustrating exemplary parameters and corresponding values that in one example are associated with each process in a computing environment such as shown in FIG. 1. The information contained in this table could be maintained and stored in any rapidly accessible memory location in the computing environment. In one example, the information is maintained in the system daemon portion 24 or the kernel 22 of RAM 18. The columns illustrate parameters for the processes shown as one process per row. Column 102 contains the name or label associated with each process. Column 104 contains data identifying whether the process is currently active (A) or has been deactivated (D). An active process is a process currently residing and running such as in RAM memory 18. A deactivated process as a process not currently residing and running in RAM memory 18, e.g., the process may have been transferred to a virtual memory location such as disk storage 16. Column 106 contains a priority rating for each process where the priority controls or at least is a factor in determining if a process will remain in or return to active status. In the illustrative example, priority scores can range from 1-100 where 100 represents the highest priority favoring the process remaining in active memory (status). Column 108 represents a value associated with the time since the respective process had a change of status. This time value can be a measurement of time, e.g., seconds, a clock value that can be compared against a running clock, or a value proportional to time or time increments. For a process with a currently active status, this would represent the length of time since the process was last previously deactivated. For a process with a currently deactivated status, this would represent the length of time since the process was last previously active. Column 110 indicates the size of memory occupied by each process, e.g., the size of each process such as measured in kilobytes or megabytes.

One objective of maintaining the information in FIG. 4 is to facilitate a more equitable selection of which specific processes should be active during times of memory pressure. The selection of processes to be deactivated or reactivated during extended times of memory pressure is important in maintaining a fair distribution of computing resources among the processes. For example, a process that is deactivated at the start of a period of memory pressure may appear to a user as though this process has crashed or become unstable where the memory pressure extends for a significant time, e.g., several to many seconds, and where the deactivated process is never allowed to the reactivated during the duration of the memory pressure. This may cause the user to take action such as attempting to terminate the “stalled” process even though the process remains stable. In turn, this may place an even further load on the computational resources.

An exemplary implementation provides for an improved and more equitable sharing of computational resources among competing processes during times of memory pressure. Referring to table 100 in FIG. 4 several exemplary processes are shown as indicated by rows 112, 114, 116, 118 and 120. In one example, it is desired that the value in column 108, representing the time since the last status change, be utilized as a significant factor in determining computational resource sharing. For example, the deactivated process of row 118 has a relatively large number value of 8 in column 108 indicating that this process has not been reactivated to receive computational resources for longer than any of the other illustrative processes. This factor makes this process deserving for consideration of reactivation.

In one example, care is to be taken not to automatically assume that an active process, i.e., process of row 112, having a substantial score of 5 in column 108 should necessarily be considered as a candidate to be deactivated based on its length of time of being active. For example, this process may be critical to the continuing stable functioning of the computing environment or may represent a user initiated process having time critical requirements. In one example, it may be inappropriate to consider this process as a candidate for the deactivation. One way of protecting such a process from deactivation is to assign a priority of a sufficiently high value so that it is unlikely or impossible for it to become a candidate for deactivation. In such a case, the priority of this process can be set by a system function with knowledge of its relative importance or by a user input. Alternatively, such important processes can be indicated such as by setting a flag associated with each process, where a corresponding flag that is set indicates that the process should not be deactivated even during an interval of memory pressure.

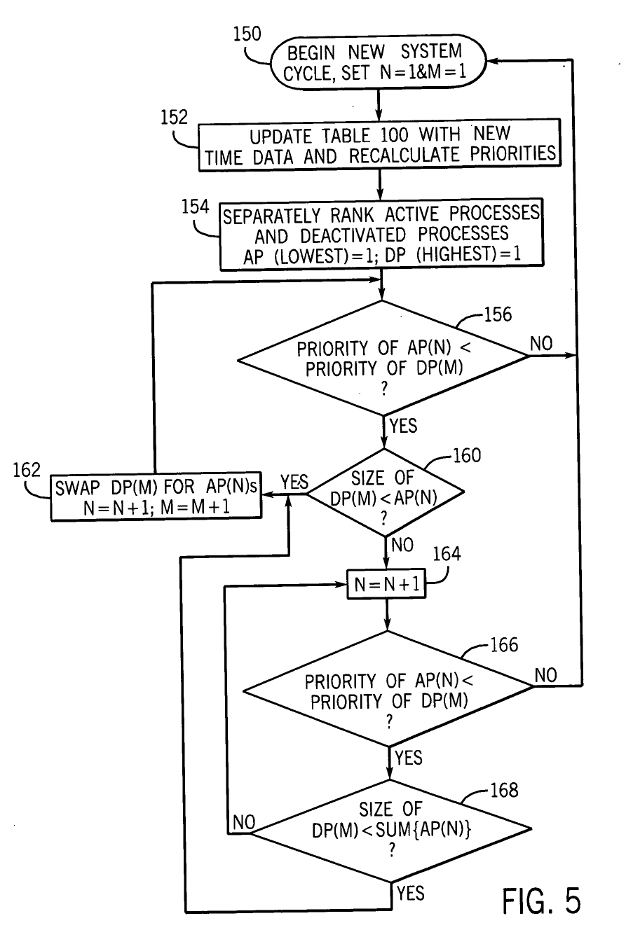

FIG. 5 is a state diagram of an exemplary logic for determining which processes will be deactivated and/or reactivated. In one example, the exemplary logic addresses the activation and reactivation of processes during each system cycle. In step 150 a new system cycle begins and variables N and M are initialized to 1. These variables, as will be explained below, are utilized to identify specific active and deactivated processes. In step 152 table 100 is updated with new time data and the corresponding priorities the processes are recalculated. As explained above, in one example the priority value for each process is a function of, at least in part, the time value as shown in column 108. That is for a deactivated process, its priority should increase as the length of time increases since its last active status. The rate at which the priority increases should be selected by the system designer to be consistent with the overall memory utilization, memory pressure and computational capacity constraints.

In step 154 the active processes and the deactivated processes are separately ranked in two groups. The active process, AP(N), with the lowest priority is identified as AP(1) with increasing subscripts identifying active processes with increasing priorities. The deactivated process, DP(M), with the highest priority is identified as DP(1) with increasing subscripts identifying deactivated processes with decreasing priorities. Exemplary step 154 indicates a separate ranking of the active and deactivated processes as a separate step. In another example, corresponding active and deactivated processes could be selected as part of and/or integrated with the comparison steps described below.

A determination is made in step 156 of whether the priority of the AP(N) is less than the priority of the DP(M). That is, does the deactivated process with the highest priority have a priority that is higher than the priority of the active process with the lowest priority? A NO determination by step 156 results in a return to the beginning 150. Since the currently considered DP as a priority lower than the correspondingly considered AP, a substitution of the DP in place of the AP is not currently warranted. A YES determination by step 156 in one example results in a further determination by step 160 in which it is determined if the size of the memory required by the DP(M) is less than the size of the memory occupied by the AP(N). A YES determination by step 160 results in the subject DP being swapped for the corresponding AP(s). That is, the corresponding AP(s) is deactivated and the resulting memory freed by this deactivation is utilized to accommodate the subject DP which is then reactivated. This provides the subject DP with an opportunity to utilize computational resources while ensuring that the swap of the DP for the AP will not result in an increase in memory pressure. As part of step 162, N and M are each incremented before returning control to the beginning of step 156 where additional DPs can be compared to APs to determine if a swap should be made.

A NO determination by step 160 results in step 164 incrementing the variable N. A determination is made in step 166 of whether the priority of an AP(N) is less than the priority of DP(M). This is similar to the comparison made by step 156 except that the AP being compared has changed to the AP with the next lowest priority, i.e., AP(N+1) is now being compared. A NO determination by step 166 in one example means that the currently considered DP does not have a priority greater than the priority of the subject AP, and a substitution is not warranted. This results in a return to the beginning 150. A YES determination by step 166 in one example results in a further determination by step 168 of whether the size of the memory required by DP(M) is less than the sum of the total memory utilized by the collective number of APs being considered. That is, it is possible to substitute a single large DP in place of a plurality of APs where each of the APs has a lower priority than the subject DP. In NO determination by step 168 returns processing to the beginning of step 164 in which additional APs will be considered for a possible swap with the subject DP. A YES determination by step 168 results in the process proceeding to step 162 in which the subject APs are deactivated in the subject DP is reactivated.

In one example, the exemplary logic of FIG. 5 accomplishes an equitable sharing of computational resources even during conditions of memory pressure. Since a deactivated process is not swapped for an active process(es) unless an appropriate size of memory is freed to accommodate the DP, this ensures that even with the equitable sharing of computational resources the memory pressure will not be exacerbated. In order to minimize the potential for threshing that could be caused by the swapping of one or more deactivated processes for active processes during each system cycle, in one example a predetermined minimum amount of time elapses before a DP can become eligible to be swapped for an AP. This will ensure that in one example only those DPs that have been without computational resources for the predetermined time will be eligible to be swapped.

Processes running on a computing system in one example are managed by deactivating active processes from random access memory at greater than a linear rate during times of memory pressure and reactivating deactivated processes back into random access memory at greater than a linear rate during times of no memory pressure. The specific candidate processes to be deactivated or reactivated in one example are selected based on assigned priorities. During times of memory pressure a deactivated process can be reactivated in one example only if the deactivated process has a higher priority than active process(es) and if the size of the candidate process for reactivation does not exceed the size of active process(es) to be deactivated.

Numerous alternative implementations of the present invention exist. Although a single memory pressure threshold is utilized in the above illustrative examples, a memory pressure window could be utilized in which an upper and a lower threshold define corresponding boundaries for the window. In such an implementation a more aggressive rate of deactivation of processes, such as explained with regard to FIG. 2, could be implemented upon used memory exceeding the upper threshold. Similarly, a more aggressive rate of reactivation of processes, such as explained with regard to FIG. 3, could be implemented upon used memory falling below the lower threshold. Management of deactivation and reactivation of processes when used memory is within the window in one example could utilize a different, less aggressive rate such as a linear rate. With regard to the table of FIG. 4, various factors in addition to the time since the last status change for a process in one example can be utilized to influence the priority rating. For example, active processes with very high priority ratings are unlikely candidates to be deactivated and that deactivated processes with very low priority ratings are unlikely candidates to be reactivated within the next one or few system cycles. In one example, the priority for such processes need not be updated during each system cycle in order to conserve computational resources. It will be understood that the exemplary table of FIG. 4 is provided for purposes of explanation and a number of examples need not utilize a table. For example, the priority for each relevant process could be computed on an as needed basis with previously computed values stored at a location in a format that need not necessarily resemble a table. With regard to FIG. 5, different steps and computations can be utilized to accomplish the various objectives, including but not limited to, an equitable sharing of computational resources by processes during times of memory pressure, accomplishing the latter by permitting deactivated processes to be swapped for active processes, accomplishing the latter by performing the swapping processes during one system cycle, and permitting such a swap to occur in one example only if the process(es) to be reactivated do not exceed the memory size of the active process(es) to be replaced. One or more CPUs could be utilized and the exemplary approaches described herein could be shared or run on one of the CPUs. A separate memory management module independent of the processor could be used to implement the exemplary approaches. These variations are offered merely as examples and are not intended to encompass all possible variations.

The apparatus 10 in one example comprises a plurality of components. A number of such components can be combined or divided in the apparatus 10. An exemplary component of the apparatus 10 employs and/or comprises a set and/or series of computer instructions written in or implemented with any of a number of programming languages, as will be appreciated by those skilled in the art.

The apparatus 10 in one example employs one or more computer-readable signal-bearing media. The computer-readable signal-bearing media store software, firmware and/or assembly language for performing one or more portions of one or more implementations of the invention. The computer-readable signal-bearing medium for the apparatus 10 in one example comprises one or more of a magnetic, electrical, optical, biological, and atomic data storage medium. For example, the computer-readable signal-bearing medium comprises floppy disks, magnetic tapes, CD-ROMs, DVD-ROMs, hard disk drives, and electronic memory.

The steps or operations described herein are just exemplary. There may be many variations to these steps or operations without departing from the spirit of the invention. For instance, the steps may be performed in a differing order, or steps may be added, deleted, or modified.

Although exemplary implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

What is claimed is:

1. A method for managing processes in a computing system, the method comprising the steps of:
determining that an amount of total memory utilized by active processes exceeds a memory pressure threshold;
deactivating at least one active process occupying space in the total memory during a first system cycle based on said determination; and
deactivating a number N of active processes during succeeding system cycles while the memory pressure threshold is exceeded, where N increases at a non-linear rate during each system cycle until the total memory utilized by active processes does not exceed the memory pressure threshold.

2. The method of claim 1, wherein the step of deactivating the at least one active process comprises transferring the at least one active process from active memory to a virtual memory storage location.

3. The method of claim 2, wherein the at least one active process is transferred from the active memory comprising random access memory and wherein the virtual memory storage location comprises a non-volatile storage media separate from the random access memory.

4. The method of claim 1, wherein the nonlinear rate of increase in the number of active processes to be deactivated comprises a geometric rate.

5. The method of claim 4, wherein N is recomputed during each system cycle as N=M*N1, where N1 is the number N utilized during the preceding system cycle and M is a number greater than 1.

6. The method of claim 1, further comprising the step of determining during each system cycle whether the memory pressure threshold remains exceeded.

7. The method of claim 6, further comprising the step of ceasing the deactivating of active processes upon the memory pressure threshold being determined not to be exceeded.

8. A computing apparatus, comprising:
processor;
random access memory of a given size coupled to the processor adapted to store active processes;
means for monitoring an amount of memory utilized by the active processes and determining if the amount of memory utilized by the active processes exceeds a memory pressure threshold;
first means for deactivating at least one active process occupying space in the random access memory during a first system cycle based on the monitoring means determining that the amount of memory utilized by the active processes exceeds a memory pressure threshold; and
second means for deactivating a number N of active processes from the random access memory during succeeding system cycles while the memory pressure threshold is exceeded, the second means causing N to increase at a non-linear rate during each system cycle until the total memory utilized by active processes in the random access memory does not exceed the memory pressure threshold.

9. The computing apparatus of claim 8, further comprising a virtual memory separate from the random access memory, wherein the first and second deactivating means transfer the deactivated processes from the random access memory to the virtual memory.

10. The computing apparatus of claim 9, wherein the virtual memory comprises a non-volatile storage media separate from the random access memory.

11. The computing apparatus of claim 8, wherein the second deactivation means causes the nonlinear rate to be a geometric rate.

12. The computing apparatus of claim 11, wherein the processor computes N during each system cycle as N=M*N1, where N1 is the number N utilized during the preceding system cycle and M is a number greater than 1.

13. The computing apparatus of claim 8, further comprising means for ceasing the deactivating of active processes upon the monitoring means determining that the memory pressure threshold is no longer being exceeded.

14. An article, comprising:
one or more computer-readable signal-bearing media; and
means in the one or more media for determining that an amount of total memory utilized by active processes exceeds a memory pressure threshold;
means in the one or more media for deactivating at least one active process occupying space in the total memory during a first system cycle based on said determination;
means in the one or more media for deactivating a number N of active processes during succeeding system cycles while the memory pressure threshold is exceeded, where N increases at a non-linear rate during each system cycle until the total memory utilized by active processes does not exceed the memory pressure threshold.

15. A method for managing processes in a computing system to provide equitable sharing of computation resources, the method comprising the step of:
determining that an amount of total random access memory utilized by active processes exceeds a memory pressure threshold and implementing the following steps while the active processes exceed the memory pressure threshold:
generating first priority rankings of the active processes in random access memory and second priority rankings of deactivated processes in separate virtual memory, where the generated first priority rankings comprises a priority value for each active process indicative of the relative merit of the respective process to maintain access to computation resources, where the generated second priority rankings comprises a priority value for each deactivated process indicative of the relative merit of the respective process to obtain access to computation resources; and
swapping a first deactivated process for one or more active processes if the first deactivated process has a priority value more meritorious for accessing computation resources than the priority value of the one or more active processes, and if an amount of memory occupied by the first deactivated process does not exceed an amount of memory collectively occupied by the one or more active processes.

16. The method of claim 15, wherein the step of swapping comprises writing the first deactivated process into the random access memory and deleting the one or more active processes from the random access memory.

17. The method of claim 15, wherein the step of generating and the step of swapping are performed during each system cycle of the computing system so that deactivation of the one or more active processes and reactivation of the deactivated process occur within the same system cycle.

18. The method of claim 15, further comprising the steps of:
determining that the first deactivated process has a priority value more meritorious for accessing computation resources than the priority value of a first active process, and that the amount of memory occupied by the first deactivated process is less than the amount of memory occupied by the first active process;
swapping the first deactivated process for the first active process.

19. The method of claim 15, further comprising the steps of:
determining that the first deactivated process has a priority value more meritorious for accessing computation resources than the priority value of a first active process, and that the amount of memory occupied by the first deactivated process exceeds the amount of memory occupied by the first active process;
determining that the first deactivated process has a priority value more meritorious for accessing computation resources than the priority value of a second active process, and that the amount of memory occupied by the first deactivated process is less than the collective amount of memory occupied by the first and second active processes;
swapping the first deactivated process for the first and second active processes.

20. The method of claim 15, further comprising the step of repeating the generating and swapping steps during one system cycle until further swapping does not meet the stated conditions.

21. The method of claim 15, further comprising the step of ceasing the generating and swapping steps upon the memory pressure threshold being determined not to be exceeded.

22. A computing apparatus that manages processes to provide equitable sharing of computation resources, the computing apparatus comprising:
processor;
random access memory and separate virtual memory both coupled to the processor, the processor adapted to compare an amount of random access memory utilized by active processes to a memory pressure threshold wherein memory pressure exists when the memory utilized by the active processes exceeds the memory pressure threshold;
the processor adapted to generate first priority rankings of the active processes in random access memory and second priority rankings of deactivated processes in separate virtual memory, where the generated first priority rankings comprises a priority value for each active process indicative of the relative merit of the respective process to maintain access to computation resources, where the generated second priority rankings comprises a priority value for each deactivated process indicative of the relative merit of the respective process to obtain access to computation resources; and
the processor adapted to swap a first deactivated process for one or more active processes if the first deactivated process has a priority value more meritorious for accessing computation resources than the priority value of the one or more active processes, and if an amount of memory occupied by the first deactivated process does not exceed an amount of memory collectively occupied by the one or more active processes.

23. The computing apparatus of claim 22, wherein the processor is adapted to perform all of the respective functions during each system cycle of the computing apparatus so that deactivation of the one or more active processes and reactivation of the deactivated process occur within the same system cycle.

24. The computing apparatus of claim 22, further comprising:
the processor adapted to determine that the first deactivated process has a priority value more meritorious for accessing computation resources than the priority value of a first active process, and that the amount of memory occupied by the first deactivated process is less than the amount of memory occupied by the first active process;
the processor adapted to swap the first deactivated process for the first active process.
